(19) United States
(12) Patent Application Publication
(10) Pub. No.: US 2025/0159815 A1
(43) Pub. Date: May 15, 2025

(54) MEMBER FOR FORMING WIRING, METHOD FOR FORMING WIRING LAYER USING MEMBER FOR FORMING WIRING, AND FORMED WIRING MEMBER

(71) Applicant: Resonac Corporation, Tokyo (JP)

(72) Inventors: Masashi OHKOSHI, Tokyo (JP); Yuka ITOH, Tokyo (JP); Shunsuke TAKAGI, Tokyo (JP); Kunihiko AKAI, Tokyo (JP); Nozomu TAKANO, Tokyo (JP); Hiroyuki IZAWA, Tokyo (JP); Daisuke FUJIMOTO, Tokyo (JP); Tomohiko KOTAKE, Tokyo (JP)

(21) Appl. No.: 18/836,527

(22) PCT Filed: Feb. 8, 2023
(86) PCT No.: PCT/JP2023/004213

§ 371 Date: Aug. 7, 2024

(30) Foreign Application Priority Data
Feb. 9, 2022 (WO) PCT/JP2022/005184
Jan. 10, 2023 (JP) 2023-001504

(51) Int. Cl. H05K 3/10; H05K 1/02

(52) U.S. Cl. CPC H05K 3/10; H05K 1/0296

(57) ABSTRACT

A member for forming wiring includes a metal layer and an adhesive layer disposed on the metal layer. The adhesive layer contains conductive particles, a thermosetting resin, and a maleimide compound. A member for forming wiring in which an adhesive layer and a metal layer are provided separately, and the adhesive layer is adherable to the metal layer at the point of use. The adhesive layer contains conductive particles, a thermosetting resin, and a maleimide compound.

### TECHNICAL FIELD

The present disclosure relates to a member for forming wiring, a method for forming a wiring layer using the member for forming wiring, and a formed wiring member.

### BACKGROUND ART

In Patent Literature 1, a method for producing a printed circuit board in which an electronic part such as an IC chip is embedded is disclosed.

### CITATION LIST

### Patent Literature

Patent Literature 1: JP 2012-191204 A

### SUMMARY OF INVENTION

### Technical Problem

In a method for producing a substrate with an embedded part of the related art, as illustrated in (a) and (b) in FIG. 8, insulating resin layers 102 and 103 are formed on both sides of an electronic part 101 with electrodes 101a provided thereon in a lamination direction. After that, as illustrated in (c) and (d) in FIG. 8, by performing laser drilling, the formation of a plating layer, the formation of an electrode by etching, and the like, via electrodes 104 and 105 reaching the respective electrodes 101a of the electronic part 101 are formed in the insulating resin layers 102 and 103, respectively. Then, as illustrated in (a) to (c) in FIG. 9, by further repeating the formation of insulating resin layers 106 and 107, the formation of via electrodes 108 by the laser drilling and the formation of the plating layer, the formation of the electrode by the etching, and the like, a substrate 110 with an embedded part is formed. However, in such a method for producing a substrate with an embedded part, it is necessary to perform a number of treatments to form one conductive layer (via electrode), and repeat such treatments until a plurality of conductive layers are formed, which makes a producing process extremely complicated.

Therefore, an adhesive including conductive particles and a metal layer such as a metal foil laminated thereon has been considered as a member for forming wiring. According to such a member for forming wiring, via disposing the member for forming wiring on the surface of a base material on which wiring is formed such that an adhesive layer faces the base material, thermocompressing the member for forming wiring to the base material, and performing a patterning treatment on the metal layer, it can be expected that a wiring layer connected to the wiring is simply formed on the base material on which the wiring is formed.

However, as a result of observing a formed wiring member obtained by the method described above in detail, it has been found that air bubbles or peeling may occur between a cured product of the adhesive and the base material. It is desirable that the member for forming wiring not only is capable of connecting the wirings with sufficient conductivity, but also has formability in which the adhesive is less likely to cause the problem described above.

Therefore, an object of the present disclosure is to provide a member for forming wiring, a method for forming a wiring layer using the member for forming wiring described above, and a formed wiring member capable of simplifying a forming process of a wiring layer connecting wirings while sufficiently suppressing the occurrence of air bubbles or peeling when forming the wiring.

### Solution to Problem

As one aspect, the present disclosure relates to a member for forming wiring. Such a member for forming wiring includes a metal layer, and an adhesive layer disposed on the metal layer. In such a member for forming wiring, the adhesive layer contains conductive particles, a thermosetting resin, and a maleimide compound.

According to the member for forming wiring described above, by the adhesive layer containing the conductive particles, it is possible to obtain electrical conduction between the metal layer to be a wiring pattern or wiring after processing, and another wiring pattern or wiring that adheres via the adhesive layer, and it is possible to simplify a forming process of a wiring layer connecting the wirings, compared to a process of the related art in which laser processing, a filled plating treatment, and the like are performed. In addition, by the adhesive layer containing the thermosetting resin and the maleimide compound, it is possible to sufficiently suppress the occurrence of air bubbles or peeling between a base material for forming the wiring layer and a cured product of the adhesive layer. Note that, the present applicant has considered that such effects are attained by the fact that it is easier to maintain a curing reaction for a long period of time, and it is easier to obtain sufficient embeddability and uniform reactivity, by combining the thermosetting resin and the maleimide compound.

The maleimide compound may include at least one type selected from the group consisting of a polymaleimide compound having at least two N-substituted maleimide groups in one molecular structure and a derivative thereof.

The derivative of the polymaleimide compound may include a modified polymaleimide compound having a structural unit derived from the polymaleimide compound and a structural unit derived from an amine compound having an amino group. In one mode, the amine compound may include an amine compound having at least two amino groups, and in the other mode, the amine compound may include an amine compound having a siloxane skeleton.

The adhesive layer may have a reaction rate of 90% or less when heated at 180° C. for 5 minutes. The thermosetting resin may be an epoxy resin.

In one aspect described above, the member for forming wiring may further include a release film. In this case, it is easier to handle the member for forming wiring as a member, and it is possible to improve an operation efficiency when forming the wiring layer using the member for forming wiring. Note that, such a release film, for example, can be used by being disposed only on any one surface of the surface of the adhesive layer on a side opposite to the metal layer and the surface of the metal layer on a side opposite to the adhesive layer, and can also be used by being disposed on both surfaces of the surface of the adhesive layer on a side opposite to the metal layer and the surface of the metal layer on a side opposite to the adhesive layer.

As another aspect, the present disclosure relates to a member for forming wiring in which an adhesive layer and a metal layer are provided separately, and the adhesive layer is adherable to the metal layer at the point of use. The adhesive layer in the member for forming wiring of another aspect contains conductive particles, a thermosetting resin, and a maleimide compound.

According to the member for forming wiring described above, it is possible to attain the same effects as those of the member for forming wiring according to one aspect described above. Further, since the adhesive layer and the metal layer can be prepared separately (as a set of the member for forming wiring), it is possible to improve the degree of operational freedom when preparing the wiring layer using the member for forming wiring, such as selecting the member for forming wiring with a more optimal material configuration.

According to the member for forming wiring described above, it is possible to attain the same effects as those of the member for forming wiring according to another aspect described above. Further, since the adhesive layer and the metal layer can be prepared separately (as a set of the member for forming wiring), it is possible to select the member for forming wiring with a more optimal material configuration, and it is possible to improve the degree of operational freedom when preparing the wiring layer using the member for forming wiring.

As still another aspect, the present disclosure relates to a method for forming a wiring layer using any one of the members for forming wiring described above. Such a method for forming a wiring layer includes preparing any one of the members for forming wiring described above, preparing a base material on which wiring is formed, disposing the member for forming wiring on a surface of the base material on which the wiring is formed such that the adhesive layer faces the base material in order to cover the wiring, thermocompressing the member for forming wiring to the base material, and performing a patterning treatment on the metal layer. According to such a forming method, it is possible to considerably simplify a processing process, compared to a method of the related art. In addition, according to such a forming method, it is possible to sufficiently suppress the occurrence of the air bubbles or the peeling between the cured product of the adhesive layer and the base material.

As still another aspect, the present disclosure relates to a formed wiring member. Such a formed wiring member includes a base material including wiring, and a cured product of the adhesive layer of any one of the members for forming wiring described above, which is disposed on the base material in order to cover the wiring. In such a formed wiring member, the wiring and the metal layer of the member for forming wiring or another wiring formed from the metal layer are electrically connected. According to such a mode, it is possible to obtain the formed wiring member in which the air bubbles or the peeling between the cured product and the base material are sufficiently reduced.

The present disclosure provides [1] to [13] described below.
[1]A member for forming wiring, including:
a metal layer; and an adhesive layer disposed on the metal layer,
in which the adhesive layer contains conductive particles, a thermosetting resin, and a maleimide compound.
[2] The member for forming wiring according to [1], in which the maleimide compound includes at least one type selected from the group consisting of a polymaleimide compound having at least two N-substituted maleimide groups in one molecular structure and a derivative thereof.
[3] The member for forming wiring according to [2], in which the derivative of the polymaleimide compound includes a modified polymaleimide compound having a structural unit derived from the polymaleimide compound and a structural unit derived from an amine compound having an amino group.
[4] The member for forming wiring according to claim 3, in which the amine compound includes an amine compound having at least two amino groups.
[5] The member for forming wiring according to [3], in which the amine compound includes an amine compound having a siloxane skeleton.
[6] The member for forming wiring according to any one of [1] to [5], in which the adhesive layer has a reaction rate of 90% or less when heated at 180° C. for 5 minutes.
[7] The member for forming wiring according to any one of [1] to [6], in which the thermosetting resin is an epoxy resin.
[8] The member for forming wiring according to any one of [1] to [7], further including a release film.
[9]A member for forming wiring in which an adhesive layer and a metal layer are provided separately, and the adhesive layer is adherable to the metal layer at the point of use,
in which the adhesive layer contains conductive particles, a thermosetting resin, and a maleimide compound.
[10] The member for forming wiring according to [8], in which the adhesive layer has a reaction rate of 90% or less when heated at 180° C. for 5 minutes.
[11] The member for forming wiring according to [8] or [9], in which the thermosetting resin is an epoxy resin.
[12]A method for forming a wiring layer, including:
preparing the member for forming wiring according to any one of [1] to [10];
preparing a base material on which wiring is formed;
disposing the member for forming wiring on a surface of the base material on which the wiring is formed such that the adhesive layer faces the base material in order to cover the wiring;
thermocompressing the member for forming wiring to the base material; and
performing a patterning treatment on the metal layer.
[13]A formed wiring member, including:
a base material including wiring; and
a cured product of the adhesive layer of the member for forming wiring according to any one of [1] to [10], which is disposed on the base material in order to cover the wiring,
in which the wiring and the metal layer of the member for forming wiring or another wiring formed from the metal layer are electrically connected.

### Advantageous Effects of Invention

According to the present disclosure, it is possible to simplify the forming process of the wiring layer connecting the wirings while sufficiently suppressing the occurrence of the air bubbles or the peeling when forming the wiring.

### BRIEF DESCRIPTION OF DRAWINGS

FIG. 1 is a cross-sectional view illustrating a member for forming wiring according to one embodiment of the present disclosure.

(a) to (d) in FIG. 2 are drawings for sequentially illustrating a method for forming a wiring layer using the member for forming wiring illustrated in FIG. 1.

(a) to (c) in FIG. 3 are cross-sectional views illustrating a member for forming wiring according to another embodiment of the present disclosure and a state in a case where such a member for forming wiring is compressed.

FIG. 4 is a cross-sectional view illustrating a member for forming wiring according to another embodiment of the present disclosure.

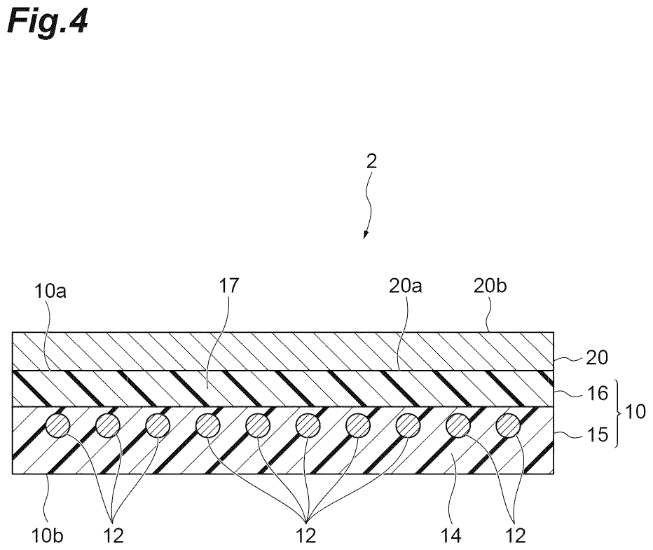

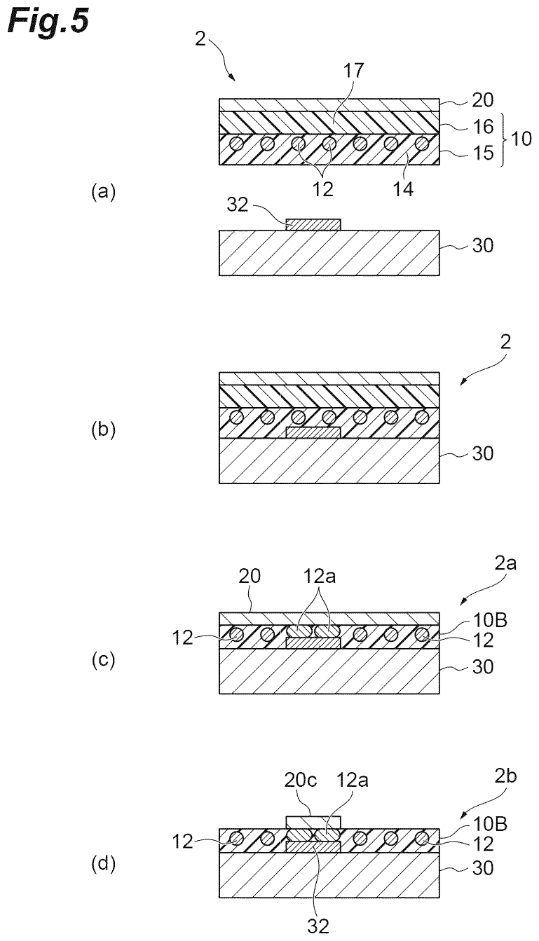

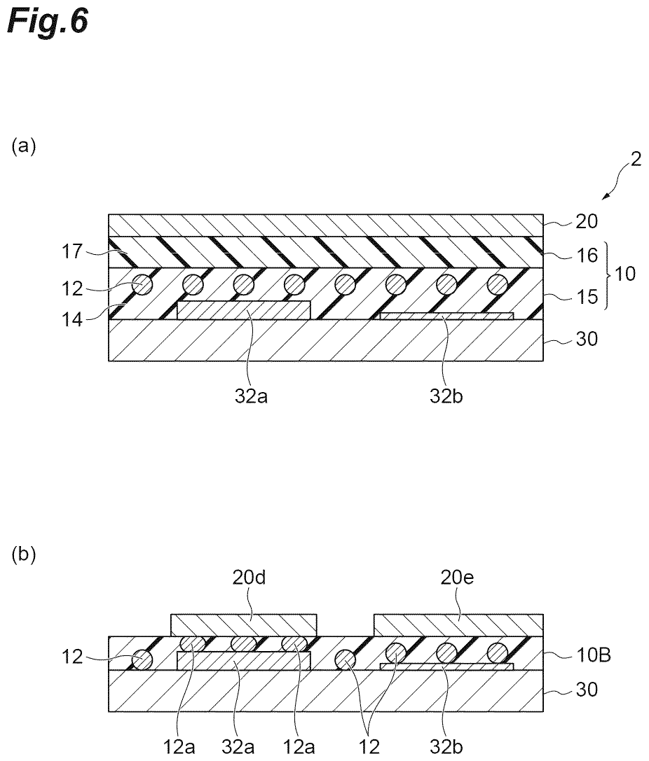

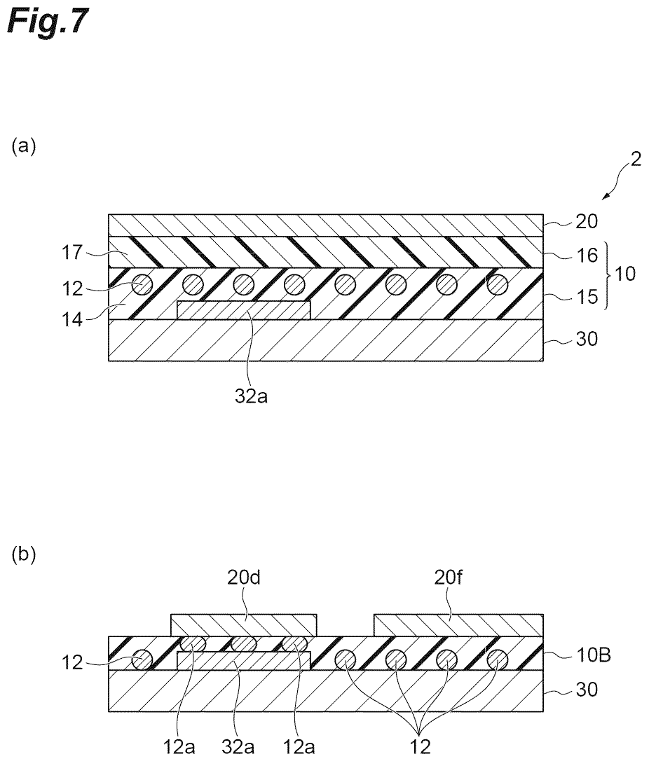

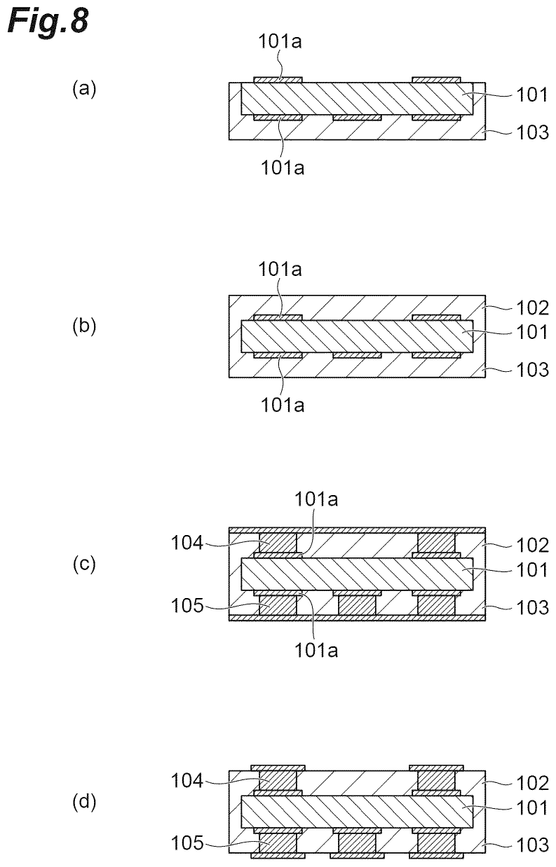

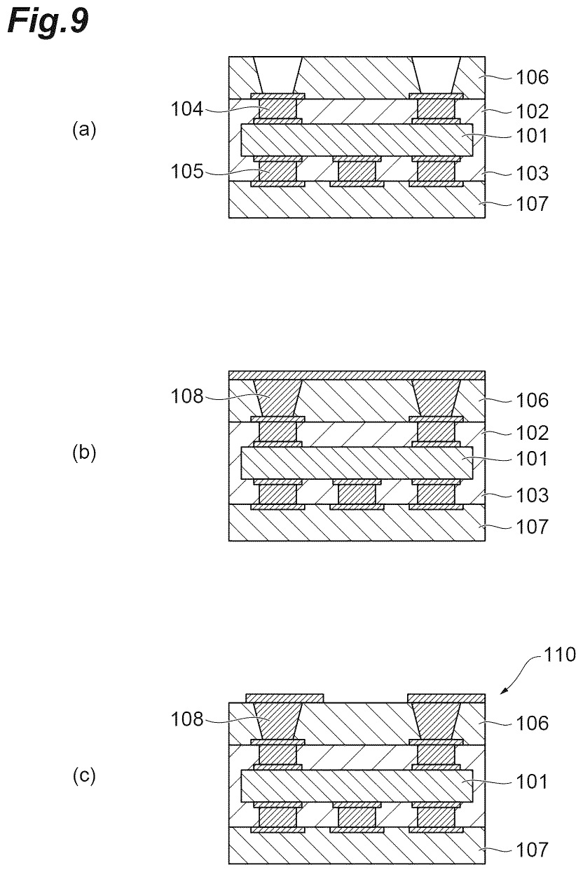

(a) to (d) in FIG. 5 are drawings for sequentially illustrating a method for forming a wiring layer using the member for forming wiring illustrated in FIG. 4.

(a) and (b) in FIG. 6 are cross-sectional views for illustrating an example in a case where a wiring layer is formed using the member for forming wiring illustrated in FIG. 4.

(a) and (b) in FIG. 7 are cross-sectional views for illustrating another example in a case where the wiring layer is formed using the member for forming wiring illustrated in FIG. 4.

(a) to (d) in FIG. 8 are cross-sectional views for sequentially illustrating a method for producing a substrate with an embedded part of the related art.

(a) to (c) in FIG. 9 are cross-sectional views for sequentially illustrating the method for producing the substrate with an embedded part of the related art, which illustrate steps subsequent to FIG. 8.

### DESCRIPTION OF EMBODIMENTS

Hereinafter, a member for forming wiring according to one embodiment of the present disclosure, and a method for forming a wiring layer using the member for forming wiring will be described with reference to the drawings. In the following description, the same reference numerals will be applied to the same or corresponding parts, and the repeated description will be omitted. In addition, a positional relationship such as the top, bottom, right, and left is based on a positional relationship illustrated in the drawings, unless otherwise specified. Further, a dimensional ratio in the drawings is not limited to that illustrated.

In this specification, a numerical range represented by using “to” includes numerical values described before and after “to” as the minimum value and the maximum value, respectively. In addition, in numerical ranges described in stages in this specification, the upper limit value or the lower limit value described in one numerical range may be replaced with the upper limit value or the lower limit value of a numerical range described in the other stage. In addition, in the numerical range described in this specification, the upper limit value or the lower limit value of the numerical range may be replaced with values described in Examples.

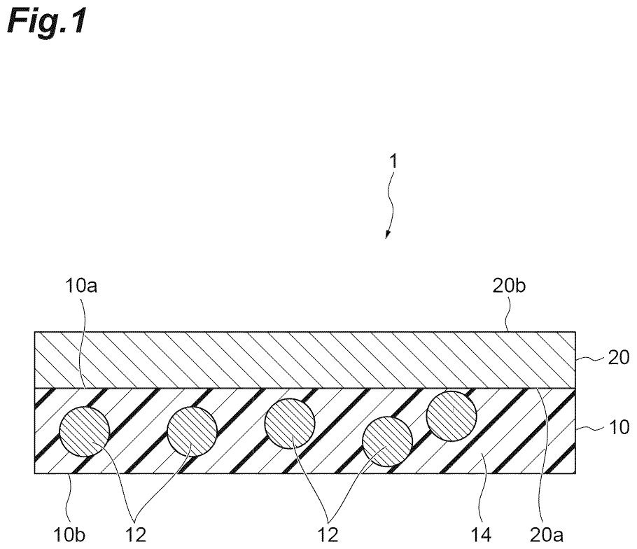

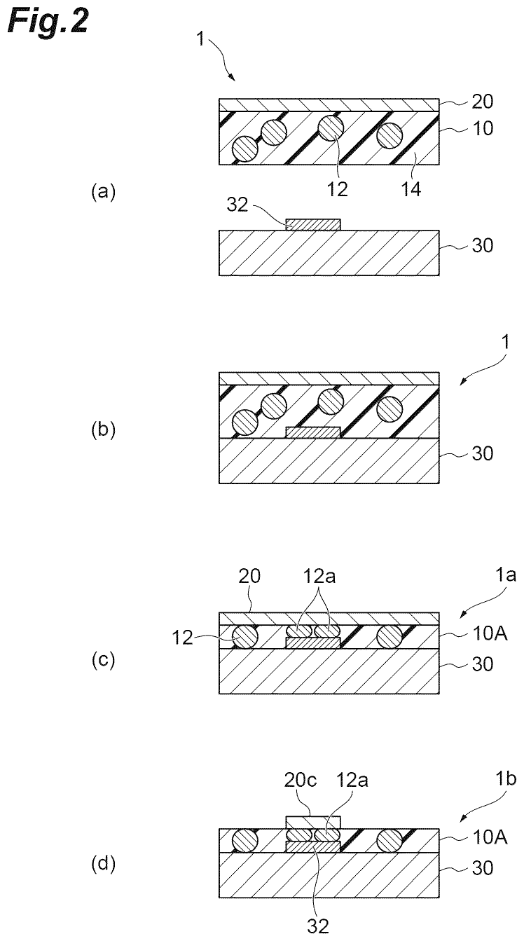

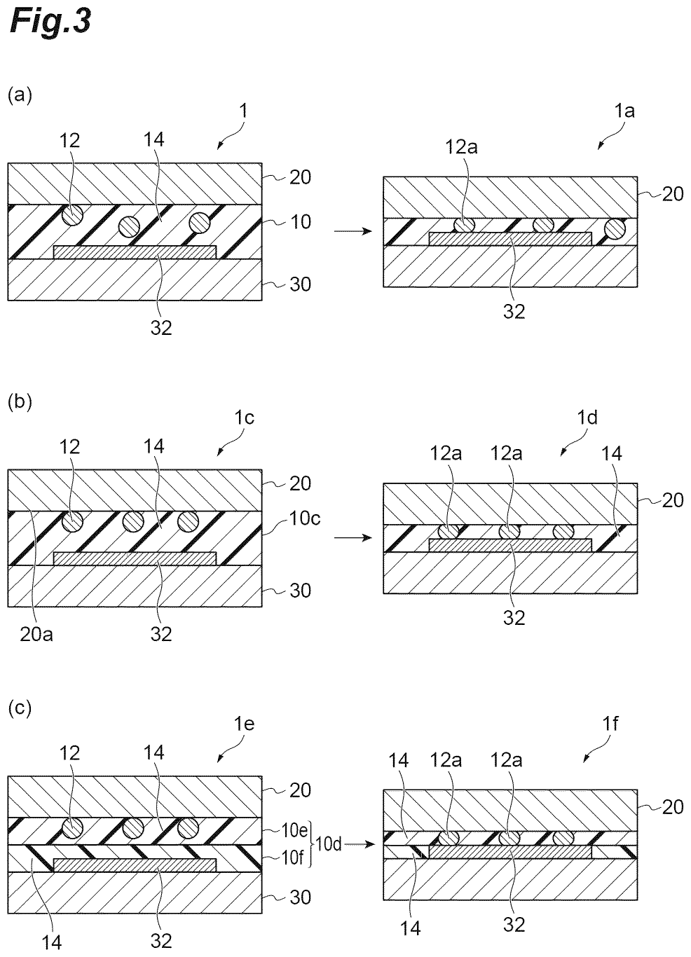

FIG. 1 is a cross-sectional view illustrating a member for forming wiring according to one embodiment of the present disclosure. As illustrated in FIG. 1, a member 1 for forming wiring is configured by including an adhesive layer 10 and a metal layer 20. The member 1 for forming wiring is not limited thereto, and for example, is a member that can be used when preparing a redistribution layer, a build-up multi-layer wiring board, a substrate with an embedded part, and the like. In addition, the member 1 for forming wiring may be used for an EMI shield or the like.

The adhesive layer 10 contains conductive particles 12, and an insulating adhesive component 14 in which the conductive particles 12 are dispersed. The adhesive layer 10, for example, has a thickness of 5 to 50 μm. The adhesive component 14 of the adhesive layer 10 is defined as a solid content other than the conductive particles 12. The adhesive layer 10 may be in a stage B state, that is, a semi-cured state, before a wiring layer is formed by the member 1 for forming wiring.

### [Configuration of Conductive Particles]

The conductive particles 12 are approximately spherical particles having conductivity, and are composed of metal particles configured of a metal such as Au, Ag, Ni, Cu, and solder, conductive carbon particles configured of conductive carbon, or the like. The conductive particles 12 may be coated conductive particles including a core containing non-conductive glass, ceramic, plastic (such as polystyrene), or the like, and a coating layer containing the metal described above or conductive carbon and covering the core. Among them, the conductive particles 12 may be metal particles formed of a hot-melt metal, or coated conductive particles including a core containing plastic, and a coating layer containing a metal or conductive carbon and covering the core. The conductive particles 12 may be metal particles (Cu particles) configured of Cu, from the viewpoint of being more excellent in connection resistance.

The conductive particles 12 may include an insulating layer. Specifically, for example, in the conductive particles of the embodiment described above, including a core (for example, polymer particles), and a coating layer covering the core, such as a metal layer, the insulating layer further covering the coating layer may be provided outside the coating layer. The insulating layer may be an outermost surface layer positioned on the outermost surface of the conductive particles. The insulating layer may be a layer formed from an insulating material such as silica and an acrylic resin.

An average particle diameter Dp of the conductive particles 12 may be 1 μm or more, may be 2 μm or more, or may be 5 μm or more, from the viewpoint of being excellent in dispersibility and conductivity. The average particle diameter Dp of the conductive particles may be 50 μm or less, may be 30 μm or less, or may be 20 μm or less, from the viewpoint of being excellent in the dispersibility and the conductivity. From the viewpoint described above, the average particle diameter Dp of the conductive particles may be 1 to 50 μm, may be 5 to 30 μm, may be 5 to 20 μm, or may be 2 to 20 μm.

The maximum particle diameter of the conductive particles 12 may be less than the minimum interval between electrodes in a wiring pattern (the shortest distance between the adjacent electrodes). The maximum particle diameter of the conductive particles 12 may be 1 μm or more, may be 2 μm or more, or may be 5 μm or more, from the viewpoint of being excellent in the dispersibility and the conductivity. The maximum particle diameter of the conductive particles may be 50 μm or less, may be 30 μm or less, or may be 20 μm or less, from the viewpoint of being excellent in the dispersibility and the conductivity. From the viewpoint described above, the maximum particle diameter of the conductive particles may be 1 to 50 μm, may be 2 to 30 μm, or may be 5 to 20 μm.

In this specification, for 300 pieces (pcs) of any particles, a particle diameter is measured by observation using a scanning electron microscope (SEM), the average value of the particle diameters obtained is set as the average particle diameter Dp, and the largest value obtained is set as the maximum particle diameter of the particles. Note that, in a case where the particles are not in a spherical shape, such as a case where the particles have a protrusion, the particle diameter of the particles is set as the diameter of a circle circumscribed around the particle in the image of SEM.

The content of the conductive particles 12 is determined in accordance with the definition of the electrode to be connected, or the like. For example, the blending amount of the conductive particles 12 is not particularly limited, but may be 0.1% by volume or more, or may be 0.2% by volume or more, on the basis of the total volume of the adhesive component (a component excluding the conductive particles in an adhesive composition). In a case where the blending amount is 0.1% by volume or more, there is a tendency that a decrease in the conductivity is suppressed. The blending amount of the conductive particles 12 may be 30% by volume or less, or may be 10% by volume or less, on the basis of the total volume of the adhesive component (the component excluding the conductive particles 12 in the adhesive composition). In a case where the blending amount is 30% by volume or less, there is a tendency that the short circuit of a circuit is less likely to occur. Note that, “% by volume” is determined on the basis of the volume of each component before curing at 23° C., but the volume of each component can be converted from weight to volume using specific weight. In addition, the component is put in a graduated cylinder or the like in which a suitable solvent (water, alcohol, or the like) for wetting the component without dissolving or swelling the component is put, and the increased volume can also be obtained as the volume of the component.

### [Configuration of Adhesive Layer/Adhesive Component]

The adhesive component 14 configuring the adhesive layer 10 may contain a thermosetting resin and a maleimide compound, from the viewpoint of sufficiently suppressing the occurrence of air bubbles or peeling when forming the wiring.

The thermosetting resin is a resin exhibiting curing properties by heat. Examples of the thermosetting resin include an epoxy resin, a polyimide resin, a triazine resin such as a melamine resin, a phenolic resin, and modified products of such resins. Among them, the thermosetting resin may be the epoxy resin, from the viewpoint of sufficiently suppressing the occurrence of the air bubbles or the peeling when forming the wiring.

The epoxy resin may be a compound having two or more epoxy groups in the molecules, and examples thereof include a bisphenol A-type epoxy resin, a bisphenol F-type epoxy resin, a bisphenol S-type epoxy resin, a biphenyl-type epoxy resin, a phenol novolac-type epoxy resin, a cresol novolac-type epoxy resin, a bisphenol A novolac-type epoxy resin, a bisphenol F novolac-type epoxy resin, a dicyclopentadiene-type epoxy resin, an alicyclic epoxy resin, an aliphatic chain epoxy resin, a glycidyl ester-type epoxy resin, an isocyanurate-type epoxy resin, a hydantoin-type epoxy resin, a glycidyl ether compound of polyfunctional phenols, a glycidyl ether compound of difunctional alcohols, hydrogen additives thereof, and the like. Only one type of such epoxy resins may be used alone, or two or more types thereof may be used together.

The adhesive component may contain a compound having three or more epoxy groups in one molecule, as the epoxy resin, from the viewpoint of ensuring an adhesive strength and heat resistance. As such a compound, a phenol novolac-type epoxy resin, a cresol novolac-type epoxy resin, a bisphenol A novolac-type epoxy resin, and a bisphenol F novolac-type epoxy resin may be used from the viewpoint of handleability and availability.

In the epoxy resin, an epoxy equivalent may be 100 to 1000 g/eq, may be 125 to 900 g/eq, or may be 150 to 800 g/eq, from the viewpoint of ensuring the adhesive strength and the heat resistance, and excellent reactivity. The epoxy equivalent is obtained by a method standardized in JIS Standard (K7236: 2001).

The content of the epoxy resin in the adhesive component may be 5 to 95% by mass, may be 10 to 90% by mass, or may be 15 to 85% by mass, on the basis of the total amount of the adhesive component (the total amount of the solid content other than the conductive particles 12 in the adhesive layer 10). The content of the epoxy resin in the adhesive component may be 20% by mass or more, and may be 80% by mass or less, 75% by mass or less, 70% by mass or less, 65% by mass or less, 60% by mass or less, 55% by mass or less, 50% by mass or less, 45% by mass or less, 40% by mass or less, 35% by mass or less, or 30% by mass or less, on the basis of the total amount of the adhesive component (the total amount of the solid content excluding the conductive particles 12 in the adhesive layer 10).

The maleimide compound is a compound having at least one N-substituted maleimide group in one molecular structure. The maleimide compound, for example, may include at least one type selected from the group consisting of a polymaleimide compound (m1) having at least two N-substituted maleimide groups in one molecular structure (hereinafter, may be referred to as the “component (m1)”) and a derivative thereof. Examples of the “derivative thereof” include an addition reactant between the polymaleimide compound (m1) and an amine compound described below, such as a diamine compound. Since the maleimide compound has low reactivity, by the adhesive component 14 containing the maleimide compound, it is expected that a curing reaction slowly proceeds. By the curing reaction slowly proceeding, it is possible to ensure a sufficient flow time, and it is possible to sufficiently suppress the occurrence of the air bubbles or the peeling when forming the wiring.

Examples of the component (m1) include N,N′-ethylene bismaleimide, N,N′-hexamethylene bismaleimide, N,N′-(1,3-phenylene) bismaleimide, N,N′-[1,3-(2-methyl phenylene)]bismaleimide, N,N′-[1,3-(4-methyl phenylene)]bismaleimide, N,N′-(1,4-phenylene) bismaleimide, bis(4-maleimide phenyl) methane, bis(3-methyl-4-maleimide phenyl) methane, 3,3-dimethyl-5,5-diethyl-4,4-diphenyl methane bismaleimide, bis(4-maleimide phenyl) ether, bis(4-maleimide phenyl) sulfone, bis(4-maleimide phenyl) sulfide, bis(4-maleimide phenyl) ketone, bis(4-maleimide cyclohexyl) methane, 1,4-bis(4-maleimide phenyl) cyclohexane, 1,4-bis(maleimide methyl) cyclohexane, 1,4-bis(maleimide methyl) benzene, 1,3-bis(4-maleimide phenoxy)benzene, 1,3-bis(3-maleimide phenoxy)benzene, bis[4-(3-maleimide phenoxy)phenyl]methane, bis[4-(4-maleimide phenoxy)phenyl]methane, 1,1-bis[4-(3-maleimide phenoxy)phenyl]ethane, 1,1-bis[4-(4-maleimide phenoxy)phenyl]ethane, 1,2-bis[4-(3-maleimide phenoxy)phenyl]ethane, 1,2-bis[4-(4-maleimide phenoxy)phenyl]ethane, 2,2-bis[4-(3-maleimide phenoxy)phenyl]propane, 2,2-bis[4-(4-maleimide phenoxy)phenyl]propane, 2,2-bis[4-(3-maleimide phenoxy)phenyl]butane, 2,2-bis[4-(4-maleimide phenoxy)phenyl]butane, 2,2-bis[4-(3-maleimide phenoxy)phenyl]-1,1,1,3,3,3-hexafluoropropane, 2,2-bis[4-(4-maleimide phenoxy)phenyl]-1,1,1,3,3,3-hexafluoropropane, 4,4-bis(3-maleimide phenoxy)biphenyl, 4,4-bis(4-maleimide phenoxy)biphenyl, bis[4-(3-maleimide phenoxy)phenyl]ketone, bis[4-(4-maleimide phenoxy)phenyl]ketone, 2,2-bis(4-maleimide phenyl) disulfide, bis(4-maleimide phenyl) disulfide, bis[4-(3-maleimide phenoxy)phenyl]sulfide, bis[4-(4-maleimide phenoxy)phenyl]sulfide, bis[4-(3-maleimide phenoxy)phenyl]sulfoxide, bis[4-(4-maleimide phenoxy)phenyl]sulfoxide, bis[4-(3-maleimide phenoxy)phenyl]sulfone, bis[4-(4-maleimide phenoxy)phenyl]sulfone, bis[4-(3-maleimide phenoxy)phenyl]ether, bis[4-(4-maleimide phenoxy)phenyl]ether, 1,4-bis[4-(4-maleimide phenoxy)-α,α-dimethyl benzyl]benzene, 1,3-bis[4-(4-maleimide phenoxy)-α,α-dimethyl benzyl]benzene, 1,4-bis[4-(3-maleimide phenoxy)-α,α-dimethyl benzyl]benzene, 1,3-bis[4-(3-maleimide phenoxy)-α,α-dimethyl benzyl]benzene, 1,4-bis[4-(4-maleimide phenoxy)-3,5-dimethyl-α,α-dimethyl benzyl]benzene, 1,3-bis[4-(4-maleimide phenoxy)-3,5-dimethyl-α,α-dimethyl benzyl]benzene, 1,4-bis[4-(3-maleimide phenoxy)-3,5-dimethyl-α,α-dimethyl benzyl]benzene, 1,3-bis[4-(3-maleimide phenoxy)-3,5-dimethyl-α,α-dimethyl benzyl]benzene, and polyphenyl methane maleimide (for example, manufactured by Daiwa Fine Chemicals Co., Ltd., product name: BMI-2300 or the like). Only one type of such maleimide compounds may be used alone, or two or more types thereof may be used together.

Among such maleimide compounds, the bis(4-maleimide phenyl) methane, the bis(4-maleimide phenyl) sulfone, the N,N′-(1,3-phenylene) bismaleimide, the 2,2-bis[4-(4-maleimide phenoxy)phenyl]propane, or the polyphenyl methane maleimide, which has a high reaction rate and can be more highly heat-resistant, is preferable, and the bis(4-maleimide phenyl) methane or the 2,2-bis[4-(4-maleimide phenoxy)phenyl]propane is particularly preferable from the viewpoint of solubility in a solvent.

The maleimide compound may contain the derivative of the polymaleimide compound (m1), from the viewpoint of solubility in an organic solvent, compatibility, and adhesiveness to a metal foil. The derivative of the polymaleimide compound (m1), for example, may include a modified polymaleimide compound (M) having a structural unit derived from the polymaleimide compound (m1) and a structural unit derived from an amine compound (m2) having an amino group (hereinafter, may be referred to as the “component (m2)”). The modified polymaleimide compound (M) can also be referred to as an addition reactant between the component (m1) and the component (m2). Note that, each of the structural unit derived from the component (m1) and the structural unit derived from the component (m2) contained in the modified polymaleimide compound (M) may consist of one type, or may consist of a combination of two or more types.

The modified polymaleimide compound (M) may be a compound having a structure represented by Formula (1) described below, which is obtained by an addition reaction between the maleimide group of the component (m1) and the amino group of the component (m2). Note that, in Formula (1), * indicates a bonding position.

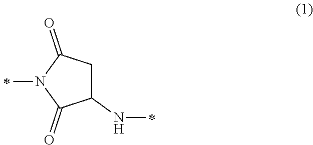

The component (m2) is preferably an amine compound (a polyamine compound) having at least two amino groups, and may be a diamine compound having two amino groups. Examples of the component (m2) include an aromatic diamine compound such as 4,4′-diaminodiphenyl methane, 4,4′-diamino-3,3′-dimethyl diphenyl methane, 3,3′-diethyl-4,4′-diaminodiphenyl methane, 4,4′-diaminodiphenyl ether, 4,4′-diaminodiphenyl sulfone, 3,3′-diaminodiphenyl sulfone, 4,4′-diaminodiphenyl ketone, 4,4′-diaminobiphenyl, 3,3′-dimethyl-4,4′-diaminobiphenyl, 2,2′-dimethyl-4,4′-diaminobiphenyl, 3,3′-dihydroxybenzidine, 2,2-bis(3-amino-4-hydroxyphenyl) propane, 3,3′-dimethyl-5,5′-diethyl-4,4′-diaminodiphenyl methane, 2,2-bis(4-aminophenyl) propane, 2,2-bis[4-(4-aminophenoxy)phenyl]propane, 1,3-bis(3-aminophenoxy) benzene, 1,3-bis(4-aminophenoxy) benzene, 1,4-bis(4-aminophenoxy) benzene, 4,4′-bis(4-aminophenoxy) biphenyl, 1,3-bis[1-[4-(4-aminophenoxy)phenyl]-1-methyl ethyl]benzene, 1,4-bis[1-[4-(4-aminophenoxy)phenyl]-1-methyl ethyl]benzene, 4,4′-[1,3-phenylene bis(1-methyl ethylidene)]bisaniline, 4,4′-[1,4-phenylene bis(1-methyl ethylidene)]bisaniline, 3,3′-[1,3-phenylene bis(1-methyl ethylidene)]bisaniline, bis[4-(4-aminophenoxy)phenyl]sulfone, bis[4-(3-aminophenoxy)phenyl]sulfone, and 9,9-bis(4-aminophenyl) fluorene; and an amine compound having a siloxane skeleton.

Among them, the component (m2) may be the amine compound having a siloxane skeleton, from the viewpoint of low thermal expansibility. That is, the modified polymaleimide compound (M) may have the structural unit derived from the polymaleimide compound (m1) and a structural unit derived from the amine compound having a siloxane skeleton.

The component (m2) may be a compound represented by General Formula (2) described below.

H₂N—X^{b4}—NH₂ (2)

In Formula (2), X^{b4} indicates a divalent organic group.

The component (m2) may contain an amine compound having a siloxane skeleton in which X^{b4} in General Formula (2) described above has a structural unit represented by General Formula (3) described below, from the viewpoint of low thermal expansibility. In addition, the component (m2) may contain an amine compound having a siloxane skeleton in which X^{b4} has a structural unit (or a group) represented by General Formula (4) described below.

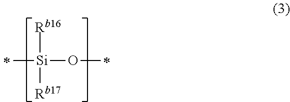

In Formula (3), R^{b16} and R^{b17} each independently represent an alkyl group having 1 to 5 carbon atoms, a phenyl group, or a substituted phenyl group. * indicates a bonding position.

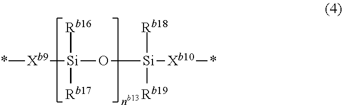

In Formula (4), R^{b16} and R^{b17} are identical to R^{b16} and R^{b17} in General Formula (3) described above, and a plurality of R^{b16}'s and R^{b17}'s may be identical to each other, or may be different from each other. R^{b18} and R^{b19} each independently indicate an alkyl group having 1 to 5 carbon atoms, a phenyl group, or a substituted phenyl group. X^{b9} and X^{b10} each independently indicate a divalent organic group, and n^{b13} indicates an integer of 2 to 100.

Examples of a substituent in the substituted phenyl group indicated by R^{b16}, R^{b17}, R^{b18}, and R^{b19} include an alkyl group having 1 to 5 carbon atoms, an alkenyl group having 2 to 5 carbon atoms, and an alkynyl group having 2 to 5 carbon atoms.

Examples of the divalent organic group indicated by X^{b9} and X^{b10} include an alkylene group, an alkenylene group, an alkynylene group, an arylene group, —O—, or a divalent linking group formed by combining the above.

The content of the structural unit derived from the component (m1) in the modified polymaleimide compound (M) is not particularly limited, but may be 50 to 95% by mass, may be 70 to 92% by mass, or may be 75 to 90% by mass.

The content of the structural unit derived from the component (m2) in the modified polymaleimide compound (M) is not particularly limited, but may be 5 to 50% by mass, may be 8 to 30% by mass, or may be 10 to 25% by mass.

The total content of the structural unit derived from the component (m1) and the structural unit derived from the component (m2) in the modified polymaleimide compound (M) is not particularly limited, but may be 80% by mass or more, may be 90% by mass or more, may be 95% by mass or more, or may be 100% by mass (that is, may consist only of the structural unit derived from the component (m1) and the structural unit derived from the component (m2)).

The molecular weight of the modified polymaleimide compound (M) may be 100 to 100000, or may be 500 to 50000 or 1000 to 10000, in terms of the weight average molecular weight.

The content of the maleimide compound in the adhesive component may be 5 to 95% by mass, may be 10 to 90% by mass, or may be 15 to 85% by mass, on the basis of the total amount of the adhesive component (the total amount of the solid content excluding the conductive particles 12 in the adhesive layer 10). The content of the maleimide compound in the adhesive component may be 20% by mass or more, 25% by mass or more, 30% by mass or more, 35% by mass or more, 40% by mass or more, 45% by mass or more, 50% by mass or more, 55% by mass or more, 60% by mass or more, 65% by mass or more, or 70% by mass or more, and may be 80% by mass or less, on the basis of the total amount of the adhesive component (the total amount of the solid content excluding the conductive particles 12 in the adhesive layer 10).

The adhesive component 14 configuring the adhesive layer 10 may further contain a curing accelerator. Examples of the curing accelerator include an imidazole-based compound, an organic phosphorus-based compound, tertiary amine, and a quaternary ammonium salt. Only one type of such curing accelerators may be used alone, or two or more types thereof may be used together. Among such curing accelerators, the imidazole-based compound is preferable.

The content of the curing accelerator in the adhesive component may be 0.001 to 10% by mass, on the basis of the total amount of the adhesive component.

The adhesive component 14 may contain other components in addition to the thermosetting resin, the maleimide compound, and the curing accelerator described above. As the other components, a filler, an antioxidant, a film-forming material, a softener, an anti-aging agent, a colorant, a flame retardant, a thixotropic agent, a coupling agent, and the like may be further contained.

Examples of the filler include an inorganic filler and an organic filler. Examples of the inorganic filler include alumina, silica, titanium oxide, clay, calcium carbonate, aluminum carbonate, magnesium silicate, aluminum silicate, mica, a glass staple fiber, aluminum borate, and silicon carbide. Examples of the organic filler include silicone particles, methacrylate/butadiene/styrene particles, acryl/silicone particles, polyamide particles, and polyimide particles. Only one type of such fillers may be used alone, or two or more types thereof may be used together.

The adhesive component 14 may contain silica particles as the filler, from the viewpoint of improving the heat resistance, improving mechanical properties, and adjusting fluidity at the point of use.

The maximum diameter of the filler may be less than the particle diameter of the conductive particles 12, or may be 0.001 to 10 μm.

The content of the filler may be 5 parts by volume to 60 parts by volume with respect to 100 parts by volume of the adhesive component. In a case where the content of the filler is 5 parts by volume to 60 parts by volume, there is a tendency that excellent connection reliability is obtained.

Examples of the antioxidant include a quinone derivative such as benzoquinone and hydroquinone, a phenol derivative (a hindered phenol derivative) such as 4-methoxyphenol and 4-t-butyl catechol, an aminoxyl derivative such as 2,2,6,6-tetramethyl piperidine-1-oxyl and 4-hydroxy-2,2,6,6-tetramethyl piperidine-1-oxyl, and a hindered amine derivative such as tetramethyl piperidyl methacrylate.

The content of the antioxidant may be 0.01% to 5% by mass, or may be 0.1% to 3% by mass, on the basis of the total amount of the adhesive component.

As the film-forming material, a thermoplastic resin is preferably used, and examples thereof include a phenoxy resin, a polyvinyl formal resin, a polystyrene resin, a polyvinyl butyral resin, a polyester resin, a polyamide resin, a xylene resin, a polyurethane resin, a polyacrylic resin, a polyester urethane resin, and the like. Further, in such polymers, a siloxane bond or a fluorine substituent may be contained. Only one type of such resins can be used alone, or two or more types thereof can be used in combination. Among the resins described above, the phenoxy resin may be used from the viewpoint of the adhesive strength, the compatibility, the heat resistance, and a mechanical strength.

As the molecular weight of the thermoplastic resin increases, film-forming properties are more easily obtained, and a melt viscosity affecting the fluidity of the film can be set in a wide range. The molecular weight of the thermoplastic resin may be 5000 to 150000, or may be 10000 to 80000, in terms of the weight average molecular weight. By setting the weight average molecular weight to 5000 or more, excellent film-forming properties are easily obtained, and by setting the weight average molecular weight to 150000 or less, excellent compatibility with other components is easily obtained.

Note that, in the present disclosure, the weight average molecular weight indicates a value measured using a calibration curve of standard polystyrene obtained by gel permeation chromatography (GPC), in accordance with the following condition.

### (Measurement Condition)

Device: manufactured by Tosoh Corporation, GPC-8020
Detector: manufactured by Tosoh Corporation, RI-8020
Column: manufactured by Hitachi Chemical Company, Ltd., Gelpack GLA160S+GLA150S
Sample concentration: 120 mg/3 mL
Solvent: tetrahydrofuran
Injection amount: 60 μL
Pressure: 2.94×106 Pa (30 kgf/cm²)
Flow rate: 1.00 mL/min

In addition, the content of the film-forming material may be 0.5% to 75% by mass, or may be 1% to 50% by mass, on the basis of the total amount of the adhesive component.

In the adhesive layer 10, a reaction rate when heated at 180° C. for 5 minutes may be 90% or less, may be 85% or less, or may be 80% or less.

The reaction rate described above indicates a value obtained by the following measurement method.

[Measurement of Reaction Rate when Heated at 180° C. for 5 Minutes]

A part of the adhesive layer is scraped off to obtain two 5 mg evaluation samples before heating. Next, one of the evaluation samples before heating is heated at 180° C. for 5 minutes to obtain an evaluation sample after heating. For each of the evaluation sample before heating and the evaluation sample after heating, a DSC calorific value is measured using a differential scanning calorimetry (DSC) device (product name: DSC7, manufactured by PerkinElmer Inc.) at a measurement temperature range of 30 to 250° C. and a temperature increase rate of 10° C./minute under a nitrogen stream. On the basis of the measured DSC calorific value, the reaction rate when heated at 180° C. for 5 minutes is obtained from the following expression.

$$Reaction Rate = ( C x - C y ) \times 100 / Cx$$

[In the expression, Cx indicates the DSC calorific value (J/g) of the evaluation sample before heating, and Cy indicates the DSC calorific value (J/g) of the evaluation sample after heating.]

The thickness of the adhesive layer may be 0.1 times or more, may be 0.2 times or more, may be 0.3 times or more, may be 0.5 times or more, may be 0.8 times or more, or may be 1 time or more the average particle diameter Dp of the conductive particles 12. The thickness of the adhesive layer may be 10 times or less, may be 7 times or less, may be 5 times or less, may be 3 times or less, may be 2 times or less, may be 1.8 times or less, may be 1.5 times or less, or may be 1 time or less the average particle diameter Dp of the conductive particles 12.

The member 1 for forming wiring may include only the adhesive layer 10 (a single-layered adhesive layer) as the adhesive layer.

The adhesive layer, for example, can be formed by preparing an application liquid for forming an adhesive layer in which the adhesive component described above, and as necessary, conductive particles are dissolved and dispersed in a solvent, applying the application liquid onto a metal layer described below (for example, a metal foil such as a copper foil), and drying the application liquid. As another method, a film-shaped adhesive may be formed by applying the application liquid for forming an adhesive layer onto a release film and drying the application liquid, and then, the film-shaped adhesive and a metal layer (for example, a metal foil such as a copper foil) may be laminated to form the adhesive layer. As the solvent, for example, methyl ethyl ketone, toluene, ethyl acetate, methyl isobutyl ketone, cyclohexanone, acetone, N-methyl-2-pyrrolidone, and the like can be used.

### [Configuration of Metal Layer]

One surface and the opposite surface of the metal layer 20 may have the same surface roughness Rz, or may have different surface roughness Rz. The metal layer 20, for example, has a thickness of 5 to 200 μm. Here, the thickness of the metal layer is a thickness including the surface roughness Rz. The metal layer 20, for example, is a copper foil, an aluminum foil, a nickel foil, a stainless-steel foil, a titanium foil, or a platinum foil.

The adhesive layer 10 is disposed on a first surface 20a of the metal layer 20. The surface roughness Rz of the first surface 20a of the metal layer 20 may be 0.3 μm or more, may be 0.5 μm or more, or may be 1.0 μm or more. In addition, the surface roughness Rz of the first surface 20a of the metal layer 20 may be 50 μm or less, may be 40 μm or less, may be 30 μm or less, may be 20 μm or less, may be less than 20 μm, may be 17 μm or less, may be 10 μm or less, may be 8.0 μm or less, may be 5.0 μm or less, or may be 3.0 μm or less. The surface roughness Rz of the first surface 20a of the metal layer 20, for example, may be 0.3 μm or more and 20 μm or less, or may be 0.3 μm or more and less than 20 μm, and more specifically, may be 0.5 μm or more and 10 μm or less. Note that, the surface roughness Rz of a second surface 20b of the metal layer 20, for example, may be 20 μm or more, may be greater than the surface roughness Rz of the first surface 20a, may be the same surface roughness as that of the first surface 20a, or may be less than the surface roughness Rz of the first surface 20a. Note that, in a case where the surface roughness Rz of the first surface 20a of the metal layer 20 is excessively low (for example, in a case where the surface roughness Rz is 0.2 μm), it is not possible to maintain the adhesiveness between the metal layer 20 and the adhesive layer 10 for a long period of time, which may cause peeling. Therefore, the surface roughness Rz of the first surface 20a of the metal layer 20 may be 0.3 μm or more. Here, by adopting a material or a connection configuration that is capable of ensuring the adhesiveness, the surface roughness Rz of the first surface 20a of the metal layer 20 may be less than 0.3 μm.

The surface roughness Rz indicates ten-point average roughness Rzjis measured on the basis of a method defined in JIS Standard (JIS B 0601-2001), and indicates a value measured using a commercially available surface roughness/contour measuring machine. For example, the surface roughness can be measured using a nano-search microscope (manufactured by SHIMADZU CORPORATION, “SFT-3500”).

Here, a relationship between the average particle diameter Dp of the conductive particles 12 and the surface roughness Rz of the first surface 20a of the metal layer 20 will be described below. In this embodiment, “surface roughness/average particle diameter” that is a ratio of the surface roughness Rz of the first surface 20a of the metal layer 20 to the average particle diameter Dp of the conductive particles 12 may be 0.03 or more, may be 0.04 or more, may be 0.05 or more, may be 0.06 or more, may be 0.1 or more, may be 0.2 or more, may be 0.3 or more, may be 0.5 or more, or may be 1 or more. In addition, “surface roughness/average particle diameter” that is the ratio of the surface roughness Rz of the first surface 20a of the metal layer 20 to the average particle diameter Dp of the conductive particles 12 may be 3 or less, may be 2 or less, may be 1.7 or less, or may be 1.5 or less. “Surface roughness/average particle diameter” that is the ratio of the surface roughness Rz of the first surface 20a of the metal layer 20 to the average particle diameter Dp of the conductive particles 12, for example, may be 0.05 or more and 3 or less, and more specifically, may be 0.06 or more and 2 or less. In this embodiment, the surface roughness Rz of the first surface 20a of the metal layer 20 and the average particle diameter Dp of the conductive particles 12 are managed such that “surface roughness/average particle diameter” that is the ratio of the surface roughness Rz of the first surface 20a of the metal layer 20 to the average particle diameter Dp of the conductive particles 12 is in a range of 0.05 to 3.

As another aspect, the present disclosure relates to a method for forming the wiring layer using the member for forming wiring. A method for forming the wiring layer using the member 1 for forming wiring described above will be described with reference to FIG. 2. (a) to (d) in FIG. 2 are drawings illustrating a method for forming a wiring layer using the member for forming wiring illustrated in FIG. 1.

First, as illustrated in (a) in FIG. 2, the member 1 for forming wiring is prepared. Further, a base material 30 on which a wiring 32 is formed is prepared. Then, the member 1 for forming wiring is disposed such that the adhesive layer 10 side of the member 1 for forming wiring faces the base material 30. After that, as illustrated in (b) in FIG. 2, by performing lamination to cover the wiring 32, the member 1 for forming wiring is stuck onto the base material 30.

Subsequently, as illustrated in (c) in FIG. 2, the member 1 for forming wiring is compressed to the base material 30 by performing predetermined heating and pressurizing on the member 1 for forming wiring. In this case, when the first surface 20a of the metal layer 20 of the member 1 for forming wiring is flat, it is possible to more reliably deform the conductive particles 12 required to ensure conductivity into conductive particles 12a in a flattened shape. Then, in a compressed member 1a for forming wiring, the flattened conductive particles 12a (accordingly, the insulating layer is damaged and a conductive portion is exposed) are disposed on the wiring 32, and reliable electrical conduction between the metal layer 20 and the wiring 32 is attained. In this case, the adhesive layer 10 is also pressed to be a thinner adhesive layer 10A.

Subsequently, as illustrated in (d) in FIG. 2, a predetermined patterning treatment (for example, an etching treatment) is performed on the metal layer 20 such that the metal layer is processed to a predetermined wiring pattern 20c (another wiring). Note that, in this case, a treatment of making the surface smooth may be implemented on the second surface 20b of the metal layer 20. The treatments of (a) to (d) in FIG. 2 described above may be repeated a predetermined number of times to form the wiring layer.

That is, the method for forming a wiring layer using the member for forming wiring includes preparing the member for forming wiring, preparing the base material on which the wiring is formed, disposing the member for forming wiring on the surface of the base material on which the wiring is formed such that the adhesive layer side faces the substrate in order to cover the wiring, thermocompressing the member for forming wiring to the base material, and performing the patterning treatment on the metal layer.

As described above, a formed wiring member 1b is formed. Such a formed wiring member 1b includes the base material 30 including the wiring 32, and a cured product of the adhesive component 14 of the member 1 for forming wiring (the adhesive layer of the thermocompressed member for forming wiring) disposed on the base material 30 to cover the wiring 32. In such a formed wiring member 1b, the wiring 32, and the metal layer 20 of the member 1 for forming wiring or the wiring pattern 20c formed (for example, etched) from the metal layer 20 are electrically connected by the conductive particles 12a. Note that, in a case where the treatments of (a) to (d) in FIG. 2 are repeated a predetermined number of times, the formed wiring member 1b may be configured by including a plurality of wiring layers (a layer in which the wirings described above are connected).

As described above, according to the method for forming a wiring layer using the member 1 for forming wiring according to this embodiment, it is possible to simplify a forming process of the wiring layer connecting the wirings, compared to a process of the related art in which laser processing, a filled plating treatment, and the like are performed. In addition, it is possible to easily make the formed wiring layer thin.

Further, according to the method for forming a wiring layer using the member 1 for forming wiring according to this embodiment, it is possible to sufficiently suppress the occurrence of the air bubbles or the peeling between the base material for forming the wiring layer and the cured product of the adhesive layer, by an effect that it is easier to maintain the curing reaction for a long period of time, and it is easier to obtain sufficient embeddability and uniform reactivity, by the adhesive layer 10 containing the thermosetting resin and the maleimide compound.

The embodiment of the present disclosure has been described in detail, but the present disclosure is not limited to the embodiment described above, and can be applied to various embodiments. For example, in the embodiment described above, as illustrated in (a) in FIG. 3, in the member 1 for forming wiring, the conductive particles 12 are dispersed in the adhesive layer 10 randomly or on average, but as illustrated in (b) in FIG. 3, the conductive particles 12 may be disposed (ubiquitously) on the metal layer 20 side. In this case, in the adhesive layer 10, the conductive particles 12 are not exposed to the second surface 10b on a side opposite to the metal layer 20, and the thickness of the adhesive layer 10 between the conductive particles 12 and the first surface 20a of the metal layer 20 may be greater than 0 or 0.1 μm and 1 μm or less. In this case, since the conductive particles 12 are disposed on the metal layer 20 side, in a wiring layer 1d, it is possible to more reliably press the conductive particles 12 into a flattened shape by the metal layer 20. In addition, as described above, by disposing ubiquitously the conductive particles 12 on the metal layer 20 side, it is possible to improve the capture rate of the conductive particles 12 with respect to the wiring (the electrode) or the like. That is, more stable conduction can be attained. Note that, the distance between the conductive particles 12 and the first surface 20a of the metal layer 20 (the thickness of the adhesive layer 10 therebetween) indicates the shortest distance from the surface of the metal layer 20 in contact with the adhesive layer 10 to the surface of the conductive particles 12, and for example, is the average value at any 30 points. In addition, the member for forming wiring is interposed between two pieces of glass (thickness: approximately 1 mm), and casted with a resin composition containing 100 g of a bisphenol A-type epoxy resin (product name: JER811, manufactured by Mitsubishi Chemical Corporation) and 10 g of a curing agent (product name: Epomount Curing Agent, manufactured by Refine Tec Ltd.), and then, the cross-sectional surface is polished using a polisher to measure the distance using a scanning electron microscope (SEM, product name: SE-8020, manufactured by Hitachi High-Tech Science Corporation).

In addition, as illustrated in (c) in FIG. 3, an adhesive layer 10d may be formed separately into a first adhesive layer 10e and a second adhesive layer 10f. An adhesive component configuring the first adhesive layer 10e and the second adhesive layer 10f may be the same as the adhesive component configuring the adhesive layer 10 described above, but there is a difference in that the conductive particles 12 are not dispersed, that is, not contained in the second adhesive layer 10f. In the member 1e for forming wiring according to such a modification example, the conductive particles 12 are dispersed, that is, contained in the first adhesive layer 10e. In this case, as with the modification example illustrated in (b) in FIG. 3, since the conductive particles 12 are disposed on the metal layer 20 side, in a wiring layer 1f, it is possible to more reliably press the conductive particles 12 into a flattened shape by the metal layer 20. In addition, as described above, by disposing ubiquitously the conductive particles 12 on the metal layer 20 side, it is possible to improve the capture rate of the conductive particles 12 with respect to the wiring (the electrode) or the like. That is, more stable conduction can be attained.

In addition, the members 1, 1c, and 1e for forming wiring may further include a release film. The release film may adhere to the surface of the adhesive layers 10, 10c, and 10d on a side opposite to the surface to which the metal layer 20 adheres, or may adhere to the surface of the metal layer 20 on a side opposite to the surface to which the adhesive layers 10, 10c, and 10d adhere. In addition, the first surface 20a of the metal layer 20 may adhere to the adhesive layers 10, 10c, and 10d, or may adhere to both thereof. In this case, it is easier to handle the member for forming wiring, and it is possible to improve an operation efficiency when forming the wiring layer using the member for forming wiring.

In addition, in the above description, a case where the member for forming wiring is a member in which the adhesive layer 10 and the metal layer 20 adhere to each other has been described as an example, but the member for forming wiring in this embodiment may be composed of a combined product such that the adhesive layer 10 and the metal layer 20 are provided separately, and the adhesive layer 10 is adherable to the first surface 20a of the metal layer 20 at the point of use. In this case, since the adhesive layer 10 and the metal layer 20 can be prepared separately (as a set of the member for forming wiring), it is possible to improve the degree of operational freedom when preparing the wiring layer using the member for forming wiring, such as selecting the member for forming wiring with a more optimal material configuration.

FIG. 4 is a cross-sectional view illustrating a member for forming wiring according to another embodiment of the present disclosure. A member 2 for forming wiring illustrated in FIG. 4 is configured by including the adhesive layer 10 containing the conductive particles 12, and the metal layer 20. The adhesive layer 10 includes a first adhesive layer 15 containing the conductive particles 12 and the adhesive component 14, and a second adhesive layer 16 containing an adhesive component 17.

The first adhesive layer 15 contains the conductive particles 12, and the insulating adhesive component 14 in which the conductive particles 12 are dispersed. The adhesive component 14 is the same as described above. In addition, the first adhesive layer 15 may have the reaction rate described above.

A thickness d1 of the first adhesive layer 15 may be 0.1 times or more, may be 0.2 times or more, may be 0.3 times or more, may be 0.5 times or more, may be 0.8 times or more, or may be 1 time or more the average particle diameter Dp of the conductive particles 12. The thickness d1 of the first adhesive layer 15 may be 10 times or less, may be 7 times or less, may be 5 times or less, may be 3 times or less, may be 2 times or less, may be 1.8 times or less, may be 1.5 times or less, or may be 1 time or less the average particle diameter Dp of the conductive particles 12.

The second adhesive layer 16 contains the insulating adhesive component 17. The insulating adhesive component 17 in the second adhesive layer 16 may be the same as or different from the adhesive component 14. The second adhesive layer 16, for example, may have a thickness of 1 to 50 μm. The adhesive component 17 of the second adhesive layer 16 is defined as a solid content other than the conductive particles. The second adhesive layer 16 may be in a stage B state, that is, a semi-cured state, before the wiring layer is formed by the member 2 for forming wiring.

A thickness d2 of the second adhesive layer 16 may be 0.1 times or more, may be 0.5 times or more, may be 0.8 times or more, or may be 1 time or more the thickness d1 of the first adhesive layer 15. The thickness d2 of the second adhesive layer 16 may be 10 times or less, may be 7 times or less, may be 5 times or less, may be 3 times or less, or may be 1 time or less the thickness d1 of the first adhesive layer 15.

Next, a method for forming the wiring layer using the member 2 for forming wiring described above will be described with reference to FIG. 5. (a) to (d) in FIG. 5 are drawings illustrating a method for forming a wiring layer using the member for forming wiring illustrated in FIG. 4.

First, as illustrated in (a) in FIG. 5, the member 2 for forming wiring is prepared. Further, the base material 30 on which the wiring 32 is formed is prepared. Then, the member 2 for forming wiring is disposed such that the adhesive layer 10 side of the member 2 for forming wiring faces the base material 30. After that, as illustrated in (b) in FIG. 5, by performing lamination to cover the wiring 32, the member 2 for forming wiring is stuck onto the base material 30.

Subsequently, as illustrated in (c) in FIG. 5, the member 2 for forming wiring is compressed to the base material 30 by performing predetermined heating and pressurizing on the member 2 for forming wiring. In this case, when the first surface 20a of the metal layer 20 of the member 2 for forming wiring is flat, it is possible to more reliably deform the conductive particles 12 required to ensure conductivity into the conductive particles 12a in a flattened shape. Then, in a compressed member 2a for forming wiring, the flattened conductive particles 12a (accordingly, the insulating layer is damaged and the conductive portion is exposed) are disposed on the wiring 32, and excellent electrical conduction between the metal layer 20 and the wiring 32 is attained. In this case, the adhesive layer 10 is also pressed to be a thinner adhesive layer 10B. In addition, since the adhesive layer 10 includes the first adhesive layer 15 in which the conductive particles are contained in the adhesive component, and the second adhesive layer 16, excellent insulating reliability is attained in the thickness direction of a portion in which conductive connection is not desired.

Subsequently, as illustrated in (d) in FIG. 5, a predetermined patterning treatment (for example, an etching treatment) is performed on the metal layer 20 such that the metal layer is processed to the predetermined wiring pattern 20c (another wiring). Note that, in this case, a treatment of making the surface smooth may be implemented on the second surface 20b of the metal layer 20. The treatments of (a) to (d) in FIG. 5 described above may be repeated a predetermined number of times to form the wiring layer.

That is, the method for forming a wiring layer using the member for forming wiring includes preparing the member for forming wiring, preparing the base material on which the wiring is formed, disposing the member for forming wiring on the surface of the base material on which the wiring is formed such that the adhesive layer side faces the substrate in order to cover the wiring, thermocompressing the member for forming wiring to the base material, and performing the patterning treatment on the metal layer.

As described above, a formed wiring member 2b is formed. Such a formed wiring member 2b includes the base material 30 including the wiring 32, and a cured product of the first adhesive layer 15 and the second adhesive layer 16 of the member 2 for forming wiring (the adhesive layer of the thermocompressed member for forming wiring) disposed on the base material 30 to cover the wiring 32. In such a formed wiring member 2b, the wiring 32, and the metal layer 20 of the member 2 for forming wiring or the wiring pattern 20c formed (for example, etched) from the metal layer 20 are electrically connected by the conductive particles 12a. Note that, in a case where the treatments of (a) to (d) in FIG. 5 are repeated a predetermined number of times, the formed wiring member 2b may be configured by including a plurality of wiring layers (a layer in which the wirings described above are connected).

As described above, according to the method for forming a wiring layer using the member 2 for forming wiring according to this embodiment, it is possible to simplify the forming process of the wiring layer connecting the wirings, compared to the process of the related art in which the laser processing, the filled plating treatment, and the like are performed. In addition, it is possible to easily make the formed wiring layer thin. Further, it is possible to sufficiently suppress the occurrence of the air bubbles or the peeling between the base material for forming the wiring layer and the cured product of the adhesive layer.

Further, according to the method for forming a wiring layer using the member 2 for forming wiring according to this embodiment, it is possible to sufficiently ensure the degree of design freedom of the wiring pattern when forming the wiring layer by the following effects.
(i) By the adhesive layer 10 including the second adhesive layer 16, even in a case where the wiring layer formed by patterning the metal layer 20 includes a portion in a lamination direction (or the thickness direction of the adhesive layer), in which conductive connection is not desired, it is easier to ensure the insulating reliability in the portion.
(ii) In the wiring layer formed by patterning the metal layer 20 or redistribution formed separately, the conductive particles 12 are less likely to be in contact with a portion other than a conductively connected portion, and a transmission loss of the wiring due to the contact of the conductive particles is likely to be suppressed.

The effects described above will be described with reference to the drawings.

(a) and (b) in FIG. 6 are cross-sectional views for illustrating an example in a case where the wiring layer is formed using the member 2 for forming wiring according to this embodiment.

(a) in FIG. 6 illustrates a state when the base material 30 including a wiring pattern 32a and a wiring pattern 32b is prepared, and the member 2 for forming wiring is disposed on the surface of the base material 30 on which the wiring pattern is formed such that the adhesive layer 10 side faces the base material 30 in order to cover the wiring patterns 32a and 32b. After that, via thermocompressing the member 2 for forming wiring to the base material 30 and performing a patterning treatment on the metal layer 20, as illustrated in (b) in FIG. 6, a formed wiring member is obtained in which a wiring pattern 20d that is conductively connected to the wiring pattern 32a and a wiring pattern 20e that is not desired to be conductively connected to the wiring pattern 32b are formed.

Here, by the adhesive layer 10 of the member 2 for forming wiring including the first adhesive layer 15 containing the conductive particles 12 and the adhesive component 14, and the second adhesive layer 16 containing the adhesive component 17 but not the conductive particles, it is possible to provide the adhesive layer with a thickness capable of ensuring a distance in which the conduction by the conductive particles 12 does not occur between the wiring pattern 20e and the wiring pattern 32b that are not desired to be conductively connected while ensuring excellent conduction between the wirings of the wiring pattern 20d and the wiring pattern 32a via the conductive particles 12 when compressed. Accordingly, the wiring pattern 20e and the wiring pattern 32b are not conductively connected, and the insulating reliability in the thickness direction of the adhesive layer can be ensured.

(a) and (b) in FIG. 7 are cross-sectional views for illustrating another example in a case where the wiring layer is formed using the member 2 for forming wiring according to this embodiment.

(a) in FIG. 7 illustrates a state when the base material 30 including the wiring pattern 32a is prepared, and the member 2 for forming wiring is disposed on the surface of the base material 30 on which the wiring pattern is formed such that the adhesive layer 10 side faces the base material 30 in order to cover the wiring pattern 32a. After that, via thermocompressing the member 2 for forming wiring to the base material 30 and performing a patterning treatment on the metal layer 20, as illustrated in (b) in FIG. 7, a formed wiring member is obtained in which the wiring pattern 20d that is conductively connected to the wiring pattern 32a and a wiring pattern 20f that is not conductively connected (or a portion in the wiring pattern that is not conductively connected) are formed.

Here, by the adhesive layer 10 of the member 2 for forming wiring including the first adhesive layer 15 containing the conductive particles 12 and the adhesive component 14, and the second adhesive layer 16 containing the adhesive component 17 but not the conductive particles, it is possible to provide the adhesive layer in which the wiring pattern 20f and the conductive particles 12 are not in contact with each other while ensuring excellent conduction between the wirings of the wiring pattern 20d and the wiring pattern 32a via the conductive particles 12 when compressed. Accordingly, in the wiring pattern 20f, the transmission loss of the wiring due to the contact of the conductive particles can be suppressed. In particular, in the member 2 for forming wiring, by laminating the metal layer 20, the second adhesive layer 16, and the first adhesive layer 15 in this order, it is easier to prevent the contact between the wiring pattern 20f and the conductive particles 12.

In the method illustrated in FIG. 7, the wiring pattern 20f may be formed by performing a patterning treatment on the metal layer 20 and forming redistribution.

In the first adhesive layer 15 of the member 2 for forming wiring illustrated in FIG. 4, the conductive particles 12 are locally disposed, but the conductive particles 12 may be dispersed in the adhesive component 14 randomly or on average.

In addition, in the first adhesive layer 15 of the member 2 for forming wiring, the conductive particles 12 are locally disposed on the second adhesive layer 16 side, but the conductive particles 12 may be locally disposed on a side opposite to the second adhesive layer 16 side (the second surface 10b side of the adhesive layer 10).

In addition, the conductive particles are not contained in the second adhesive layer 16 of the member 2 for forming wiring, but the second adhesive layer 16 may contain a part of the particle bodies of the conductive particles 12 (in other words, may not contain all the particle bodies of the conductive particles 12).

In addition, the adhesive layer 10 of the member 2 for forming wiring may be composed of two layers of the first adhesive layer 15 and the second adhesive layer 16, or may be composed of three or more layers including layers (for example, a third adhesive layer) in addition to the first adhesive layer 15 and the second adhesive layer 16. The third adhesive layer may be a layer having the same composition as the composition described above for the first adhesive layer 15 or the second adhesive layer 16, or may be a layer having the same thickness as the thickness described above for the first adhesive layer 15 or the second adhesive layer 16. For example, the member 2 for forming wiring may be configured by sequentially laminating the metal layer, the third adhesive layer, the second adhesive layer, and the first adhesive layer, or may be configured by sequentially laminating the metal layer, the second adhesive layer, the first adhesive layer, and the third adhesive layer, but is not limited thereto.

In addition, the member 2 for forming wiring may further include a release film. The release film may adhere to the surface of the adhesive layer 10 (the second surface 10b side of the adhesive layer 10) on a side opposite to the surface to which the metal layer 20 adheres, may adhere to the surface of the metal layer 20 (the second surface 20b side of the metal layer 20) on a side opposite to the surface to which the adhesive layer 10 adheres (the first surface 10a of the metal layer), or may adhere to both thereof. In this case, it is easier to handle the member for forming wiring, and it is possible to improve the operation efficiency when forming the wiring layer using the member for forming wiring.

In addition, in the above description, a case where the member for forming wiring is a member in which the adhesive layer 10 and the metal layer 20 adhere to each other has been described as an example, but the member 2 for forming wiring in this embodiment may be composed of a combined product such that the adhesive layer 10 and the metal layer 20 are provided separately, and the adhesive layer 10 is adherable to the first surface 20a of the metal layer 20 at the point of use. In this case, since the adhesive layer 10 and the metal layer 20 can be prepared separately (as a set of the member for forming wiring), it is possible to improve the degree of operational freedom when preparing the wiring layer using the member for forming wiring, such as selecting the member for forming wiring with a more optimal material configuration.

### EXAMPLES

Hereinafter, the present disclosure will be described in more detail by Examples. However, the present disclosure is not limited to Examples.

### Synthesis Example 1: Synthesis of Modified Polymaleimide Compound

100 g of dual-end type diamine-modified siloxane (manufactured by Shin-Etsu Chemical Co., Ltd., product name: X-22-161A, functional equivalent of amino group: 800 g/mol), 450 g of 2,2-bis[4-(4-maleimide phenoxy)phenyl]propane, and 550 g of propylene glycol monomethyl ether were put in a 2 L reaction container provided with a thermometer, a stirrer, and a moisture meter with a reflux cooling tube, in which heating and cooling can be performed, and then, a reaction was performed at 120° C. for 3 hours to obtain a solution containing a modified polymaleimide compound. The weight average molecular weight (Mw) of the obtained modified maleimide resin was 2500.

### <Preparation of Adhesive Component>

As an adhesive component, the followings were prepared.

### (Thermosetting Resin)

Epoxy resin (A): NC-7000L (a naphthol aralkyl cresol copolymerizable epoxy resin, manufactured by Nippon Kayaku Co., Ltd., product name, epoxy equivalent: 230 g/eq)

### (Maleimide Compound)

Maleimide compound (A): the modified polymaleimide compound of Synthesis Example 1

### (Curing Accelerator)

Curing accelerator (A): G-8009L (isocyanate-masked imidazole, manufactured by DKS Co. Ltd., product name)

### (Antioxidant)

Antioxidant (A): YOSHINOX BB (a phenol derivative, manufactured by Mitsubishi Chemical Corporation, product name)

### <Preparation of Conductive Particles>

As conductive particles, the followings were prepared.

### (Conductive Particles (1))

As conductive particles (1), gold-plated resin particles (resin material: a styrene-divinyl benzene copolymer), conductive particles with an average particle diameter of 10 μm and specific weight of 1.8 were prepared.

### (Conductive Particles (2))

As conductive particles (2), gold-plated resin particles (resin material: a styrene-divinyl benzene copolymer), conductive particles with an average particle diameter of 20 μm and specific weight of 1.7 were prepared.

### (Conductive Particles (3))

As conductive particles (3), gold-plated resin particles (resin material: a styrene-divinyl benzene copolymer), conductive particles with an average particle diameter of 30 μm and specific weight of 1.5 were prepared.

### (Conductive Particles (4))

As conductive particles (4), Cu particles, conductive particles with an average particle diameter of 10 μm and specific weight of 8.9 were prepared.

(Conductive Particles (5)) As conductive particles (5), Cu particles, conductive particles with an average particle diameter of 20 μm and specific weight of 8.9 were prepared.

### <Preparation of Member for Forming Wiring>

### Example 1

14.61 g of the epoxy resin (A), 40.90 g of the maleimide compound (A), 0.17 g of the curing accelerator (A), and 0.080 g of the antioxidant (A) were dissolved in 25.8 g of methyl ethyl ketone (MEK), and then, 1.03 g of the conductive particles (1) were added thereto to prepare an application liquid for forming an adhesive layer.

Such an application liquid was applied onto one surface (surface roughness Rz: 3.0 μm) of a copper foil (3EC-M3-VLP, manufactured by MITSUI MINING & SMELTING CO., LTD., thickness: 12 μm) using a coater (manufactured by Yasui Seiki Company, Ltd., product name: Precision Coater), and was dried with hot air at 160° C. for 10 minutes to prepare an adhesive layer with a thickness of 10 μm on the copper foil.

### Example 2

An adhesive layer was prepared on the copper foil by the same method as that in Example 1, except that the type and the blending amount of the conductive particles were changed as shown in Table 1, and the adhesive layer with a thickness of 20 μm was formed on the copper foil.

### Example 3

An adhesive layer was prepared on the copper foil by the same method as that in Example 1, except that the type and the blending amount of the conductive particles were changed as shown in Table 1, and the adhesive layer with a thickness of 30 μm was formed on the copper foil.

### Example 4

An adhesive layer was prepared on the copper foil by the same method as that in Example 1, except that the type and the blending amount of the conductive particles were changed as shown in Table 1, and the adhesive layer with a thickness of 10 μm was formed on the copper foil.

### Example 5

An adhesive layer was prepared on the copper foil by the same method as that in Example 1, except that the type and the blending amount of the conductive particles were changed as shown in Table 1, and the adhesive layer with a thickness of 20 μm was formed on the copper foil.

### Comparative Example 1

25 parts by mass of a phenoxy resin (manufactured by Union Carbide Corporation, PKHC), 10 parts by mass of a resin in which acrylic rubber microparticles were dispersed in a bisphenol A-type epoxy resin (content of acrylic microparticles: 17% by mass, epoxy equivalent: 220 to 240 g/eq), 10 parts by mass of a cresol novolac-type epoxy resin (epoxy equivalent: 163 to 175 g/eq), 10 parts by mass of silica microparticles (manufactured by Shin-Etsu Chemical Co., Ltd., KMP-605, average particle diameter: 2 μm), 10 parts by mass of Ni particles (manufactured by FUKUDA METAL FOIL & POWDER CO., LTD., NiPF-BQ, average particle diameter: 5 μm), 55 parts by mass of a curing agent (manufactured by ASAHI KASEI KOGYO CO., LTD., a masterbatch-type curing agent obtained by dispersing a microcapsule-type curing agent with an average particle diameter of 5 μm, which contains an imidazole-modified product as a core of which the surface is covered with polyurethane, in a liquid bisphenol F-type epoxy resin), 60 parts by mass of toluene, and 60 parts by mass of ethyl acetate were blended to prepare an application liquid for forming an adhesive layer.

Such an application liquid was applied onto one surface (surface roughness Rz: 3.0 μm) of a copper foil (3EC-M3-VLP, manufactured by MITSUI MINING & SMELTING CO., LTD., thickness: 12 μm) using a coater (manufactured by Yasui Seiki Company, Ltd., product name: Precision Coater), and was dried with hot air at 160° C. for 10 minutes to prepare an adhesive layer with a thickness of 10 μm on the copper foil.

[Measurement of Reaction Rate when Heated at 180° C. for 5 Minutes]

For the adhesive layer prepared as described above, a reaction rate when heated at 180° C. for 5 minutes was obtained in accordance with the following method. A part of the adhesive layer was scraped off to obtain two 5 mg evaluation samples before heating. Next, one of the evaluation samples before heating was heated at 180° C. for 5 minutes to obtain an evaluation sample after heating. For each of the evaluation sample before heating and the evaluation sample after heating, a DSC calorific value was measured using a differential scanning calorimetry (DSC) device (product name: DSC7, manufactured by PerkinElmer Inc.) at a measurement temperature range of 30 to 250° C. and a temperature increase rate of 10° C./minute under a nitrogen stream. On the basis of the measured DSC calorific value, the reaction rate when heated at 180° C. for 5 minutes was obtained from the following expression.

$$Reaction Rate = ( C x - C y ) \times 100 / Cx$$

[In the expression, Cx indicates the DSC calorific value (J/g) of the evaluation sample before heating, and Cy indicates the DSC calorific value (J/g) of the evaluation sample after heating.]

For the member for forming wiring prepared as described above, the evaluation of formability and the measurement of a connection resistance value were performed in accordance with the following method.

### [Evaluation of Formability]

### <Preparation of Evaluation Sample>

The member for forming wiring with a size of 250 mm×250 mm was stuck to a circuit board (PWB) including a copper circuit with 1.0 mmϕ, a pitch of 1.5 mm, and a thickness of 12 μm on a fiberglass-impregnated epoxy substrate. This was heated and pressurized at 240° C. and 2 MPa for 90 minutes using a thermocompressing device, and was connected to prepare a connected product. Note that, in Comparative Example 1, the connection was performed by heating and pressurizing at 180° C. and 2 MPa for 30 minutes, and a connected product was prepared.

A sample in which a resist was formed on the prepared connected product was immersed in an etching solution, and was oscillated. The etching solution was prepared with copper chloride: 100 g/L and hydrochloric acid: 100 m1/L. When a predetermined copper foil portion was removed, washing was performed with pure water. After that, the resist was peeled, and a desired evaluation sample was obtained.

### <Observation of Evaluation Sample>

For the prepared evaluation sample, the appearance was visually observed, the presence or absence of air bubbles or peeling was observed, and the formability was evaluated in accordance with the following evaluation criterion.

### (Evaluation Criterion)

A: in the evaluation sample, the air bubbles or the peeling are not observed in an area range of 90% or more.
B: in the evaluation sample, the air bubbles or the peeling are not observed in an area range of 70% or more and less than 90%.
C: in the evaluation sample, the air bubbles or the peeling are observed in an area range of greater than 30% or the entire range.

### [Measurement of Connection Resistance Value]

### <Preparation of Evaluation Sample>

The member for forming wiring was stuck to a circuit board (PWB) including three copper circuits with a line width of 1000 μm, a pitch of 10000 μm, and a thickness of 15 μm on a fiberglass-impregnated epoxy substrate. This was heated and pressurized at 180° C. and 2 MPa for 60 minutes using a thermocompressing device (heating type: constant heating, manufactured by Toray Engineering Co., Ltd.), and was connected over a width of 2 mm to prepare a connected product.

A sample in which a resist was formed on the prepared connected product was immersed in an etching solution, and was oscillated. The etching solution was adjusted with copper chloride: 100 g/L and hydrochloric acid: 100 m1/L. When a predetermined copper foil portion was removed, washing was performed with pure water. After that, the resist was peeled, and a desired evaluation sample was obtained.

### <Measurement of Evaluation Sample>

A resistance value between the copper foil portion remaining on the circuit and the copper circuit on the substrate was measured with a multimeter immediately after adhesion. The resistance value was indicated as the average of 37 resistance points between the copper foil portion remaining on the circuit and the copper circuit on the substrate.

TABLE 1

| | | | | | | | | Comp. |
|---|---|---|---|---|---|---|---|---|
| | | | Exam. 1 | Exam. 2 | Exam. 3 | Exam. 4 | Exam. 5 | Exam. 1 |
| Adhesive | Thermosetting | Epoxy resin (A) | 14.61 | 14.61 | 14.61 | 14.61 | 14.61 | Refer to |
| component | resin | | | | | | | above |
| (g) | Maleimide | Maleimide | 40.90 | 40.90 | 40.90 | 40.90 | 40.90 | |
| | compound | compound (A) | | | | | | |
| | Curing | Curing | 0.17 | 0.17 | 0.17 | 0.17 | 0.17 | |
| | accelerator | accelerator (A) | | | | | | |
| | Antioxidant | Antioxidant (A) | 0.08 | 0.08 | 0.08 | 0.08 | 0.08 | |

| Conductive | Conductive particles (1) | 1.03 | — | — | — | — | |
|---|---|---|---|---|---|---|---|
| particles | Conductive particles (2) | — | 0.94 | — | | — | |
| (g) | Conductive particles (3) | — | — | 0.85 | — | — | |
| | Conductive particles (4) | — | — | — | 2.78 | — | |
| | Conductive particles (5) | — | — | — | — | 5.56 | |
| Reaction rate (%) of adhesive layer | | 55 | 54 | 54 | 53 | 53 | 98 |
| Connection | Formability | A | A | A | A | A | C |
| characteristic | Connection resistance value (mΩ) | 2.2 | 2.3 | 2.0 | 0.8 | 1.1 | 14.3 |

### REFERENCE SIGNS LIST

1, 1a, 1c, 1e: member for forming wiring, 1d, 1f: wiring layer, 1b: formed wiring member, 2: member for forming wiring, 10, 10c, 10d, 10A, 10B: adhesive layer, 10a: first surface, 10b: second surface, 10e: first adhesive layer, 10f: second adhesive layer, 12, 12a: conductive particles, 14: adhesive component, 15: first adhesive layer, 16: second adhesive layer, 17: adhesive component, 20: metal layer, 20a: first surface, 20b: second surface, 30: base material, 20c: wiring pattern, 32: wiring.

1. A member for forming wiring, comprising:
a metal layer; and
an adhesive layer disposed on the metal layer,
wherein the adhesive layer comprises conductive particles, a thermosetting resin, and a maleimide compound.

2. The member for forming wiring according to claim 1,
wherein the maleimide compound comprises at least one type selected from the group consisting of a polymaleimide compound having at least two N-substituted maleimide groups in one molecular structure and a derivative thereof.

3. The member for forming wiring according to claim 2,
wherein the derivative of the polymaleimide compound comprises a modified polymaleimide compound having a structural unit derived from the polymaleimide compound and a structural unit derived from an amine compound having an amino group.

4. The member for forming wiring according to claim 3,
wherein the amine compound comprises an amine compound having at least two amino groups.

5. The member for forming wiring according to claim 3,
wherein the amine compound comprises an amine compound having a siloxane skeleton.

6. The member for forming wiring according to claim 1,
wherein the adhesive layer has a reaction rate of 90% or less when heated at 180° C. for 5 minutes.

7. The member for forming wiring according to claim 1,
wherein the thermosetting resin is an epoxy resin.

8. The member for forming wiring according to claim 1, further comprising a release film.

9. A member for forming wiring in which an adhesive layer and a metal layer are provided separately, and the adhesive layer is adherable to the metal layer at the point of use,
wherein the adhesive layer comprises conductive particles, a thermosetting resin, and a maleimide compound.

10. The member for forming wiring according to claim 9,
wherein the adhesive layer has a reaction rate of 90% or less when heated at 180° C. for 5 minutes.

11. The member for forming wiring according to claim 9,
wherein the thermosetting resin is an epoxy resin.

12. A method for forming a wiring layer, comprising:
preparing the member for forming wiring according to claim 1;
preparing a base material on which wiring is formed;
disposing the member for forming wiring on a surface of the base material on which the wiring is formed such that the adhesive layer faces the base material in order to cover the wiring;
thermocompressing the member for forming wiring to the base material; and
performing a patterning treatment on the metal layer.

13. A formed wiring member, comprising:
a base material comprising wiring; and
a cured product of the adhesive layer of the member for forming wiring according to claim 1, which is disposed on the base material in order to cover the wiring,
wherein the wiring and the metal layer of the member for forming wiring or another wiring formed from the metal layer are electrically connected.

14. A method for forming a wiring layer, comprising:
preparing the member for forming wiring according to claim 9;
preparing a base material on which wiring is formed;
disposing the member for forming wiring on a surface of the base material on which the wiring is formed such that the adhesive layer faces the base material in order to cover the wiring;
thermocompressing the member for forming wiring to the base material; and
performing a patterning treatment on the metal layer.

15. A formed wiring member, comprising:
a base material comprising wiring; and
a cured product of the adhesive layer of the member for forming wiring according to claim 9, which is disposed on the base material in order to cover the wiring,
wherein the wiring and the metal layer of the member for forming wiring or another wiring formed from the metal layer are electrically connected.
